(19) United States
(12) Patent Application Publication
(10) Pub. No.: US 2016/0336423 A1
(43) Pub. Date: Nov. 17, 2016

(54) METHOD OF MANUFACTURING SILICON CARBIDE SEMICONDUCTOR DEVICE

(71) Applicant: TOYOTA JIDOSHA KABUSHIKI KAISHA, Toyota-shi (JP)

(72) Inventors: Hiroki MIYAKE, Toyota-shi (JP); Tatsuji NAGAOKA, Toyota-shi (JP)

(73) Assignee: TOYOTA JIDOSHA KABUSHIKI KAISHA, Toyota-shi (JP)

(21) Appl. No.: 15/152,673

(22) Filed: May 12, 2016

(30) Foreign Application Priority Data
May 15, 2015 (JP) 2015-099610

(51) Int. Cl. H01L 29/66; H01L 21/311; H01L 21/02; H01L 29/16; H01L 21/04

(52) U.S. Cl. CPC H01L 29/6606; H01L 29/1608; H01L 21/0495; H01L 21/02236; H01L 21/31111; H01L 29/66143; H01L 21/02255

(57) ABSTRACT

A semiconductor structure is formed in a SiC substrate. A thermal oxide film is formed on a front surface of the SiC substrate. An opening reaching the front surface of the SiC substrate is formed by etching a part of the thermal oxide film. The opening is filled with a material that becomes a Schottky electrode. Forming a sacrificial thermal oxide film on the front surface of the SiC substrate is not executed after the forming of the semiconductor structure and before the forming of the thermal oxide film.

### CROSS-REFERENCE TO RELATED APPLICATION

This application claims priority to Japanese Patent Application No. 2015-099610 filed on May 15, 2015, the entire contents of which are hereby incorporated by reference into the present application.

### TECHNICAL FIELD

There has been known a semiconductor device in which a front surface of a silicon carbide substrate (referred to as a SiC substrate) is covered with a thermal oxide film, an opening is provided in the thermal oxide film, and a Schottky electrode is provided on the front surface of the SiC substrate exposed at the opening. Disclosed herein is a method of manufacturing the semiconductor device.

### DESCRIPTION OF RELATED ART

A method of manufacturing a semiconductor device including the above-described configuration is disclosed in Japanese Patent Application Publication No. 2007-115875 and Japanese Patent Application Publication No. 2007-184571. The manufacturing method includes steps described below:
(a) thermally treating a SiC substrate in an oxygen atmosphere, and forming a sacrificial thermal oxide film on a front surface of the SiC substrate;
(b) removing the thermal oxide film by using an etchant;
   By the two steps described above, a crystal layer of low quality that exists in a front surface layer of the SiC substrate is removed.
(c) thermally treating the SiC substrate again in the oxygen atmosphere, and forming a thermal oxide film on the front surface of the SiC substrate;
   A field insulating film is formed by the thermal oxide film described above.
(d) forming an opening by removing a part of the field insulating film by using the etchant, the SiC substrate being exposed at that opening, and
(e) forming a material that becomes a Schottky electrode on the front surface of the SiC substrate exposed at the opening.

FIG. 3 shows the manufacturing method disclosed in Japanese Patent Application Publication No. 2007-115875, which method executes the following steps:
S1: crystal-growing an n-type SiC crystal layer 31 on an n-type SiC original substrate 30; The SiC original substrate 30 and the SiC crystal layer 31 will hereinafter collectively be referred to as a SiC substrate.
S2: implanting p-type ions from the front surface of the SiC substrate into an area to form a guard ring;
S3: forming a cap layer 34 that prevents precipitation of C from the SiC substrate during a thermal treatment;
S4: activating the p-type ions by a thermal treatment and forming a p-type guard ring 33, and afterwards removing the cap layer 34;
SA: forming a sacrificial thermal oxide film 35 on the front surface of the SiC substrate;
SB: removing the sacrificial thermal oxide film 35;
   The front surface of the SiC substrate is damaged as the cap layer 34 is removed. In the art in Japanese Patent Application Publication No. 2007-115875, the front surface of the SiC substrate is ground after the removal of the cap layer 34. By the grinding also, the front surface of the SiC substrate is damaged. By executing (SA) and (SB) described above, a crystal layer of low quality that exists at the front surface of the SiC substrate is removed.
S5: forming a thermal oxide film 37 on the front surface of the SiC substrate;
S6: forming a rear surface electrode 40 on a rear surface of the SiC substrate, and afterwards executing a thermal treatment to thereby bring the SiC substrate and the rear surface electrode 40 into ohmic contact with each other;
S7: forming an opening 37a by removing a part of the thermal oxide film 37, the front surface of the SiC substrate being exposed at the opening 37a and
S8: filling a material that becomes a Schottky electrode in the opening 37a, and forming an electrode 38 that is in Schottky contact with the SiC substrate.

A Schottky diode is thereby manufactured.

### SUMMARY

If a Schottky electrode is formed on a front surface of a SiC substrate by the above-described conventional method, a leakage current larger than assumed undesirably flows. A study on the cause thereof estimated the following causes, and by adopting the art to address them, a leakage current was able to be reduced.
(i) Unlike a Si substrate, a SiC substrate has many threading dislocations.
(ii) When the SiC substrate is thermally treated in an oxygen atmosphere, oxidation proceeds along the threading dislocations.
(iii) When a thermal oxide film is removed, pits (nano-level minute nanopits) are disadvantageously formed in the front surface of the substrate at a position where the oxidation has proceeded deep along the threading dislocations.
(iv) The above-described nanopits cause a leakage current to be larger than assumed.

Appl. Phys. Lett. 100, 242102 (2012) reported that nanopits that exist in a front surface of a substrate becomes a source of the leakage.

In the conventional manufacturing method, as Shown in (a) and (c) described in Paragraph 0002, or as shown in (SA) and (S5) described in Paragraph 0003, the thermal oxide film is formed twice on the front surface of the SiC substrate. Consequently, a phenomenon in which the nanopits are formed in the front surface of the SiC substrate proceeds, causing an increase in leakage current.

Disclosed herein is a manufacturing method that addresses the above matters and enables manufacturing of a silicon carbide semiconductor device having a small leakage current.

A manufacturing method disclosed herein comprises: forming a semiconductor structure including a combination of areas in a SiC substrate; forming a thermal oxide film on a front surface of the SiC substrate; forming an opening reaching the front surface of the SiC substrate by etching a part of the thermal oxide film; and filling the opening with a material that becomes a Schottky electrode. The manufacturing method is characterized in that forming a sacrificial thermal oxide film on the front surface of the SiC substrate is not executed after the forming of the semiconductor structure and before the forming of the thermal oxide film.

According to the above-described manufacturing method, the sacrificial oxide film is not formed, and hence generation of nanopits is suppressed, and generation of a leakage source is suppressed. Moreover, the thermal oxide film is removed in the opening. At this occasion, a crystal layer of low quality that exists at the front surface of the SiC substrate is removed. Even though the steps of forming and removing the sacrificial oxide film are eliminated, characteristics of the semiconductor device are not deteriorated.

During the forming of the thermal oxide film, the SiC substrate is preferably exposed to a dry oxygen atmosphere at 1100 degrees Celsius or higher or a wet oxygen atmosphere at 900 degrees Celsius or higher. With the oxidation under the above-described conditions, an oxidizing phenomenon tends to proceed isotropically, and a phenomenon in which oxidation significantly proceeds along threading dislocations can be suppressed. The generation of nanopits can be suppressed.

Moreover, the thermal oxide film is preferably formed to have a film thickness of 5 nm or greater and 20 nm or less. With the thickness of 5 nm or greater, the thermal oxide film can be utilized as a field insulating film, and moreover, the crystal layer of low quality that exists at the front surface of the SiC substrate exposed at the opening can be removed. With the thickness of 20 nm or less, the phenomenon in which oxidation significantly proceeds along threading dislocations in association with thermal oxidation can be suppressed.

According to the present manufacturing method, the forming step of the sacrificial thermal oxide film and the removing step of the sacrificial thermal oxide film can be eliminated, and the manufacturing process is thereby simplified. Furthermore, the generation of nanopits is suppressed, realizing a silicon carbide semiconductor device that has a small leakage current.

### BRIEF DESCRIPTION OF DRAWINGS

FIG. 1 is a drawing that shows steps of manufacturing a semiconductor device in an embodiment;

FIG. 2A is a drawing that shows a measurement result of a relation between a reverse voltage and a leakage current when a thermal oxide film 37 is set to have a film thickness of 30 nm;

FIG. 2B is a drawing that shows a measurement result of a relation between a reverse voltage and a leakage current when the thermal oxide film 37 is set to have a film thickness of 10 nm; and

FIG. 3 is a drawing that shows steps of a conventional manufacturing method.

### DETAILED DESCRIPTION

A feature of the art herein disclosed will hereinafter be summarized. Notably, the item described below has technical usefulness by itself.

(Feature 1) The present manufacturing method may be applied to a Schottky diode, a Schottky Barrier Diode (SBD), or a merged pin Schottky diode.

### Embodiment

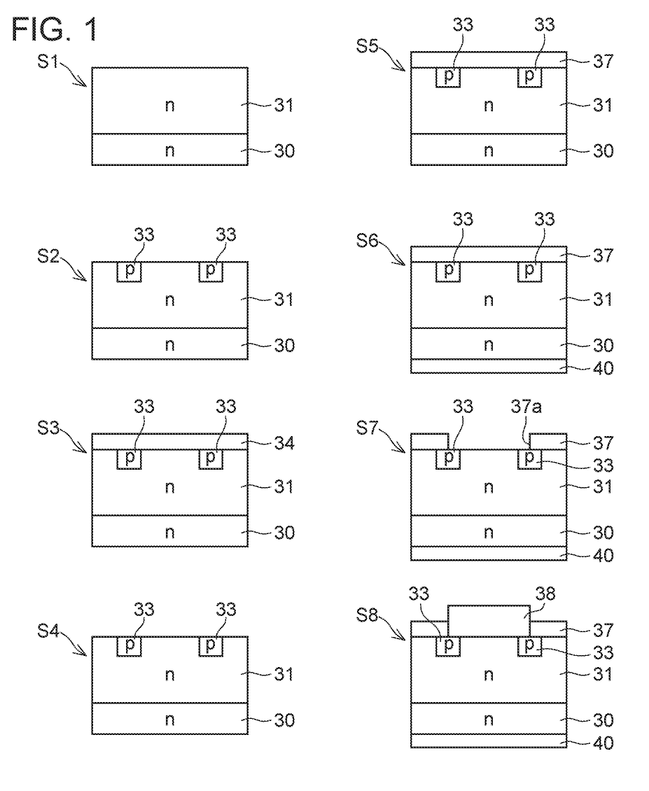

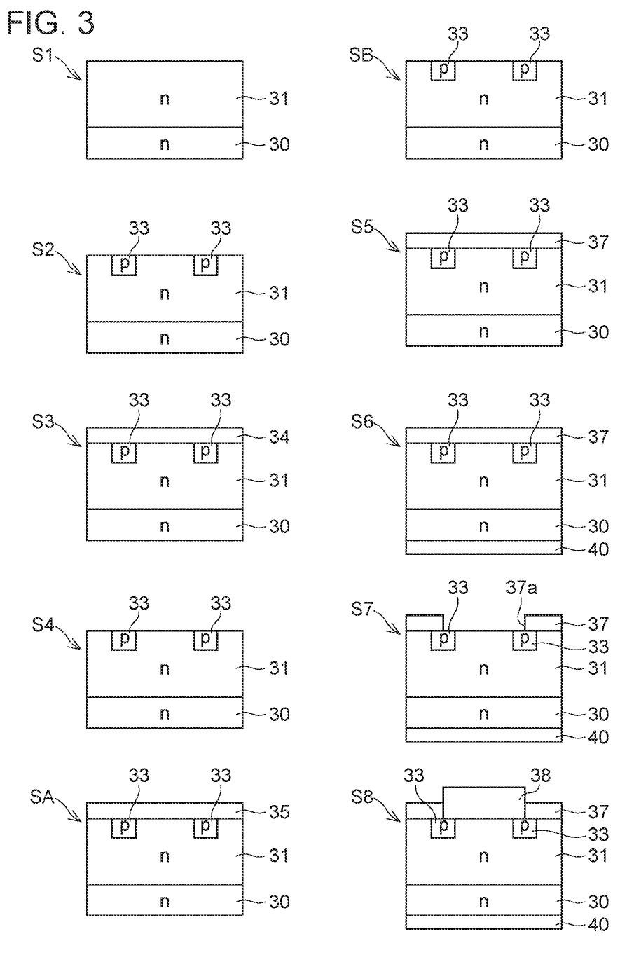

FIG. 1 shows an embodiment in which the present manufacturing method is applied to manufacturing of a Schottky diode. In distinct contrast to FIG. 3, the steps (SA) and (SB) in FIG. 3 are eliminated. A leakage current in the Schottky diode is thereby reduced. A Schottky diode is manufactured by a method comprising:
S1: crystal-growing an n-type SiC crystal layer 31 on an n-type SiC original substrate 30; The SiC original substrate 30 and the SiC crystal layer 31 will hereinafter collectively be referred to as a SiC substrate.
S2: implanting P-type ions from a front surface of the SiC substrate into an area to form a guard ring;
S3: forming a cap layer 34 that prevents precipitation of C from the SiC substrate while a thermal treatment is proceeding;
S4: activating the p-type ions by thermal treatment, and forming a p-type guard ring 33, and afterwards, removing the cap layer 34; A semiconductor structure that operates as a Schottky diode and a semiconductor structure that secures its breakdown voltage are formed in the SiC substrate by the above-described steps. When electrodes 38 and 40, which will be described later, are formed, the semiconductor structure that becomes a Schottky diode is completed with a combination of the n-type areas 30 and 31 and the p-type area 33, along with the electrodes 38 and 40.
   The front surface of the SiC substrate has been damaged in association with the removal of the cap layer 34. in this method, however, a step of removing a crystal layer of low quality is not executed at this stage.
S5: forming a thermal oxide film 37 on the front surface of the SiC substrate;
S6: forming the rear surface electrode 40 on a rear surface of the SiC substrate; and afterwards, executing a thermal treatment to thereby bring the SiC substrate and the rear surface electrode 40 into ohmic contact with each other; At this stage of the thermal treatment, the thermal oxide film 37 has been formed on the front surface of the SiC substrate, and hence no thermal oxide film is newly formed. With this thermal treatment, the thermal oxide film 37 becomes thick. A phenomenon in which oxidation proceeds along threading dislocations develops to a significant degree at a stage where the thermal oxide film is thin, whereas the same phenomenon is suppressed when the thermal oxide film has become thick. The thermal treatment that brings the rear surface electrode 40 into ohmic contact does not promote the phenomenon in which the oxidation proceeds along threading dislocations.
S7: forming an opening 37a by removing a part of the thermal oxide film 37, wherein the front surface of the SiC substrate is exposed at the opening 37a; At this occasion, a crystal layer of low quality that exists at the front surface of the SiC substrate is removed.
S8: filling a material that becomes a Schottky electrode in the opening 37a, and forming the electrode 38 that is in Schottky contact with the SiC substrate. The remaining thermal oxide film 37 becomes a field insulating film.

A Schottky diode is manufactured as described above. In the above-described method, forming a sacrificial thermal oxide film on the front surface of the SiC substrate is not executed after the forming of the semiconductor structure in the SiC substrate and before the forming of the thermal oxide film 37 that serves as the field insulating film.

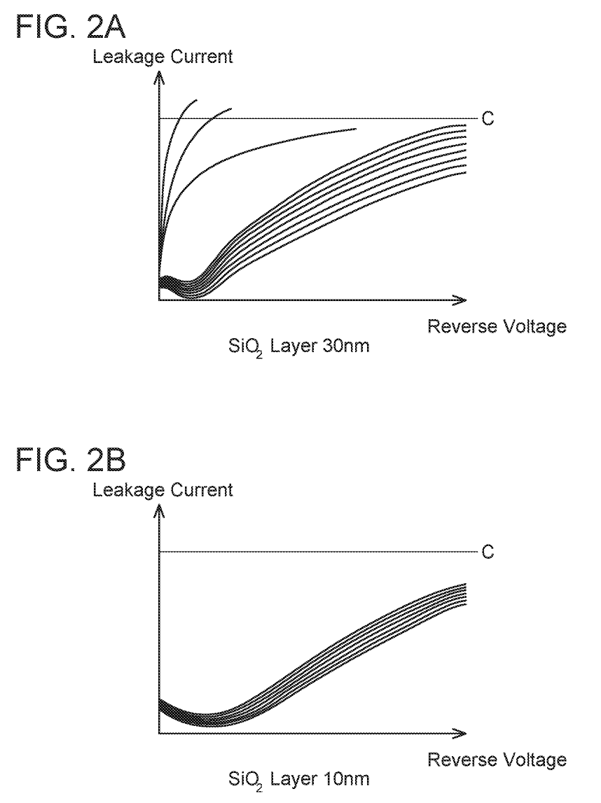

FIG. 2A and FIG. 2B each shows a measurement result of a reverse voltage applied to the Schottky diode and a leakage current. Each curve shows a measurement result of each diode. FIG. 2A shows the case where the thermal oxide film 37 is set to have a film thickness of 30 nm in S5 of FIG. 1. FIG. 2B shows the case where the thermal oxide film 37 is set to have a film thickness of 10 nm in S5 of FIG. 1. In each case, measurement results for a total of 150 diodes are presented in a superposed manner. A level C shows an allowable value of the leakage current.

As shown in FIG. 2A, when the thermal oxide film 37 was set to have a film thickness of 30 nm, a leakage current exceeded the allowable value in a considerable number of diodes. In contrast, as shown in FIG. 2B, when the thermal oxide film 37 is set to have the thickness of 10 nm, the leakage current does not exceed the allowable value. Experiments revealed that, when the thermal oxide film 37 is set to have a film thickness of 20 nm or less, the leakage current does not exceed the allowable value. The leakage current can be suppressed by eliminating the steps of forming and removing the sacrificial thermal oxide film, and furthermore, it was revealed that setting the thickness of the thermal oxide film 37, which serves as a field insulating film, to 20 nm or less is preferable.

In the present embodiment, the thermal oxide film 37 solely serves as the field insulating film. In a case where the thermal oxide film 37 with a thickness of 20 nm or less is insufficient to serve as a field insulating film, an oxide film can be deposited on a front surface of the thermal oxide film 37. The thermal oxide film and the oxide film thus deposited can serve as a field insulating film.

The thermal oxide film 37 preferably has a thickness of 5 nm or greater. With a thickness of 5 nm or greater, a low-quality layer at the front surface of the SiC substrate can be removed during the forming of the opening 37a, and a relation in which the electrode 38 and the SiC substrate are in Schottky contact with each other can be obtained.

In the present embodiment, a Schottky diode is manufactured. However, the present teachings can also be applied to manufacturing of a Schottky Barrier Diode in which p-type areas are distributedly disposed in the n-type crystal layer 31, and a depletion layer that extends from each of the p-type areas to the n-type crystal layer 31 when a reverse voltage is applied, is utilized to suppress the leakage current and increase a breakdown voltage. Moreover, the present teachings can also be applied to manufacturing of a merged pin Schottky diode. The types of Schottky diodes to which the present teachings can be applied are not particularly limited.

Specific examples of the present invention have been described in detail, however, these are mere exemplary indications and thus do not limit the scope of the claims. The art described in the claims includes modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A method of manufacturing a silicon carbide semiconductor device, the method comprising:
forming a semiconductor structure including a combination of areas in a SiC substrate;
forming a thermal oxide film on a surface of the SiC substrate;
forming an opening reaching the surface of the SIC substrate by etching a part of the thermal oxide film; and
filling material that becomes a Schottky electrode in the opening,
wherein
forming a sacrificial oxide film on the surface of the SiC substrate is not executed after the forming of the semiconductor structure and before the forming of the thermal oxide film.

2. The method according to claim 1, wherein
the thermal oxide film is formed at 1100 degrees Celsius or higher in oxygen atmosphere or at 900 degrees Celsius or higher in a wet oxygen atmosphere.

3. The method according to claim 1, wherein
the thermal oxide film is formed to have a film thickness of 5 nm or greater and 20 nm or less.
